(19) United States
(12) Patent Application Publication
(10) Pub. No.: US 2024/0105528 A1
(43) Pub. Date: Mar. 28, 2024

(54) SEMICONDUCTOR PACKAGE AND SEMICONDUCTOR ELECTRONIC DEVICE

(71) Applicant: KYOCERA Corporation, Kyoto-shi, Kyoto (JP)

(72) Inventor: Takeo SATAKE, Kyoto-shi (JP)

(73) Assignee: KYOCERA Corporation, Kyoto-shi, Kyoto (JP)

(21) Appl. No.: 18/274,832

(22) PCT Filed: Jan. 28, 2022
(86) PCT No.: PCT/JP2022/003198

§ 371 Date: Jul. 28, 2023

(30) Foreign Application Priority Data
Jan. 29, 2021 (JP) 2021-012716

(51) Int. Cl. H01L 23/053

(52) U.S. Cl. CPC H01L 23/053

(57) ABSTRACT

A semiconductor package includes: a substrate having an upper surface, a plate including a through-hole, a wall forming, together with the plate, a frame-shaped housing, and a frame. The frame-shaped housing is located on the substrate, and the frame is located on the frame-shaped housing. A space above the substrate and enclosed by the frame-shaped housing is a mounting area of an electronic component. The plate includes the through-hole passing through in a planar direction of the upper surface and includes a recess on an upper end face facing the frame.

### TECHNICAL FIELD

The present disclosure relates to a semiconductor package and a semiconductor electronic device.

### BACKGROUND OF INVENTION

A known semiconductor package houses electronic components, such as semiconductor elements, and the like such that the electronic components and the like can be used. International Publication No. 2017/038582 describes a semiconductor package taking into consideration the problems of warpage, deformation, and the like due to heating and the like during manufacturing, testing, and the like, and having a structure for suppressing such warpage, deformation, and the like.

### SUMMARY

### Solution to Problem

In an aspect of the present disclosure, a semiconductor package includes: a substrate having an upper surface, a plate including a through-hole, a wall forming, together with the plate, a frame-shaped housing, and a frame. The frame-shaped housing is located on the substrate. The frame is located on the frame-shaped housing. A space above the substrate and enclosed by the frame-shaped housing is a mounting area of an electronic component. The plate includes the through-hole passing through in a planar direction of the upper surface and includes a recess on a surface facing the frame.

### BRIEF DESCRIPTION OF THE DRAWINGS

FIG. 1 is a perspective view illustrating the overall shape of a semiconductor package.

FIG. 2 is an exploded perspective view illustrating each component of the semiconductor package.

FIG. 3 is a view of a plate viewed from the side of an inner surface.

FIG. 4 is an enlarged plan view of a portion near the plate as viewed from above.

### DESCRIPTION OF EMBODIMENTS

An embodiment is described below with reference to the attached drawings.

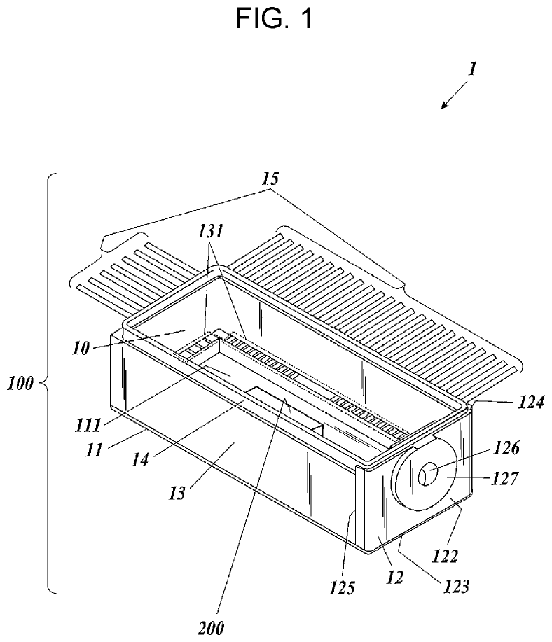

FIG. 1 is a perspective view illustrating the overall shape of a semiconductor electronic device 1.

The semiconductor electronic device 1 includes a semiconductor package 100 and an electronic component 200.

The semiconductor package 100 includes a substrate 11, a plate 12, a wall 13, a frame 14, and a plurality of leads 15.

The substrate 11 is a flat bottom plate of the semiconductor package 100 and has an upper surface 111. In the present disclosure, the terms “upper” and “lower” are defined with respect to the direction of gravity in the posture of the semiconductor package 100, which is regarded as a reference. Thus, the substrate 11 is located on the lower side, and the frame 14 is located on the upper side. The substrate 11 is, for example, rectangular in plan view as viewed in a direction perpendicular to the upper surface 111. Alternatively, the shape of the substrate 11 may be square or other than rectangular in plan view. For example, the substrate 11 may have a shape without corners, such as an oval shape. The surface of the substrate 11 may include a metal layer formed of nickel, gold, or the like. Thus, oxidation corrosion of the substrate 11 is suppressed. The metal layer may be formed, for example, by electroplating or electroless plating.

The plate 12 and the wall 13 are located on the upper surface 111 of the substrate 11 and form a frame-shaped housing enclosing the entire upper surface 111, including the mounting range of the electronic component 200, in a rectangular shape in plan view in a direction perpendicular to the upper surface 111. In other words, the semiconductor package 100 is box-shaped with a space 10 (cavity) enclosed by the substrate 11, the plate 12, and the wall 13. The space 10 is a mounting area of the electronic component 200, and the electronic component 200 is located on the upper surface 111, which is a bottom surface of the space 10.

The plate 12 forms one surface (side surface) enclosing the space 10. The plate 12 has an inner surface 121 facing the space 10, an outer surface 122 opposite to the inner surface 121, a lower end face 123 joined to the substrate 11, an upper end face 124 (the face facing the frame 14) opposite to the lower end face 123, and two side end faces 125 facing and joined to the wall 13. The plate 12 includes a through-hole 126 passing through between the inner surface 121 and the outer surface 122 in a direction along the upper surface 111 (planar direction). The plate 12 includes a protrusion 127 (second protrusion) on the outer surface 122. The through-hole 126 is located substantially at the center of the protrusion 127 as viewed in a direction perpendicular to the outer surface 122. The protrusion 127 has a pipe shape (cylindrical shape) in which the outer edge (the edge of the protrusion 127) and the inner edge (the edge of the through-hole 126) each form a substantially annular shape. The through-hole 126 enables an optical fiber, an optical waveguide, or optical signals themselves to pass through the through-hole 126 when the optical signals or the like is input/output to/from the electronic component 200. A plurality of optical fibers and/or optical waveguides may be bundled together in a tube, for example. The size and shape of the through-hole 126 may be changed to match the size, shape, and/or the like of the above-described tube and a fixing terminal of the tube. In other words, the edge of the through-hole 126 may be a contact surface of the fixing terminal and clearly define the fixing position of the tube. The outer edge of the protrusion 127 may be a surface to which the above-described fixing terminal is adhered by an adhesive material.

The wall 13 forms three surfaces (side surfaces) enclosing the space 10. The plurality of leads 15, insulated and separated from each other, are fixed to the outer surface of the wall 13. Connection terminals 131, each electrically connected to a respective one of the plurality of leads 15, are arranged in a stepped portion on an inner surface side of the wall 13. The connection terminals 131 are insulated and separated from each other. The connection terminals 131 are electrically connected to respective terminals of the electronic component 200 via bonding wires or the like (not shown) and signals and the like are transmitted.

The leads 15 are members for electrically connecting the electronic component 200 to external electronic devices and the like. The length of each portion of each lead 15 may be appropriately determined. The leads 15 extend in a plane parallel to the upper surface 111, and thus signal lines are likely to be more securely connected to the external electronic components.

Signal lines connecting the leads 15 and the connection terminals 131 pass through the wall 13 having insulating property. A portion including the signal lines may be inserted, as a wiring board separated from the other portions of the wall 13, through an opening or notch of the wall 13 having conductive or insulating property. The widths and intervals of the leads 15, the connection terminals 131, and the signal lines may be defined according to the frequency and the like of the signals to be transmitted. The signal lines may have a microstrip line structure or a coplanar structure, for example, and a conductive grounding surface for such a structure may be disposed across an insulating member insulating the signal lines. The signal lines, the connection terminals 131, and the grounding surface are metal materials such as copper, silver, gold, aluminum, nickel, chrome, or the like.

The wall 13 is a ceramic material, such as aluminum oxide (alumina), aluminum nitride, silicon nitride, mullite, or the like.

Note that the plate 12 and the wall 13 are not limited to enclosing the entire upper surface 111 of the substrate 11. In other words, the plate 12 and the wall 13 are not limited to being in contact with the periphery of the upper surface 111. The plate 12 and the wall 13 may be disposed to enclose only a part of the upper surface 111, as long as the mounting range of the electronic component 200 is enclosed.

The frame 14 is an annular member that is located on the upper end face 124 of the plate 12 and a surface of the wall 13 on a side opposite to the substrate 11 (i.e., located above the frame-shaped housing) and that is joined to the plate 12 and the wall 13. The upper surface of the frame 14 is flat and can be easily and evenly joined to a lid (not shown). If not necessary, the semiconductor electronic device 1 is not limited to including the lid.

The substrate 11, the plate 12, the frame 14, and the leads 15 are formed of, for example, a metal material such as copper, iron, tungsten, molybdenum, nickel, or cobalt, an alloy material containing several of these metal materials, or a composite material obtained by combining a metal material and an alloy material. If a part of the wall 13 is made of a conductor, such a part may also be formed of the above-described metal material, alloy material, or composite material. These components may be formed of the same material, such as a FeNiCo alloy (Kovar). By forming these components with the same material, joining is more securely performed. These components may have a high thermal conductivity of, for example, 15 to 450 W/(m.K). This enables the heat generated by the operation of the electronic component 200 to be efficiently radiated to the outside.

Furthermore, these components may have a Young's modulus of, for example, 100 to 500 GPa and a thermal expansion coefficient of, for example, 5×10⁻⁶ to 25×10⁻⁶/° C.

In the semiconductor package 100, the substrate 11, the plate 12, the wall 13, the frame 14, and the leads 15 are joined to each other by a joining material such as a brazing material. The brazing material contains mainly, for example, silver, copper, gold, aluminum, magnesium, or the like. The brazing material may also contain nickel, cadmium, phosphorus, and/or the like as additives. During joining, the brazing material melted by heating is poured onto the joint surface of the members to be joined, thereby pressurizing and fixing the members, and thereafter the brazing material cools and solidifies to thereby join the members.

The electronic component 200 is, for example, a semiconductor element that emits or detects light as described above, in other words, a laser diode, a photodiode, a photocoupler, or the like. The electronic component 200 is fixed to the upper surface 111 of the substrate 11 in an appropriate position relation and orientation with respect to the connection terminals 131 and the through-hole 126. Note that the electronic component 200 may be insulated with respect to the substrate 11; in such a case, the electronic component 200 may be disposed on an insulating film or a base of an insulating member located on the upper surface of the substrate 11, instead of being disposed directly on the substrate 11. The electronic component 200 is not limited to one. A plurality of electronic components 200 may be disposed within the space 10. The plurality of electronic components 200 may be of different types. For example, one of the electronic components 200 may be a semiconductor element such as an IC, an LSI, or the like.

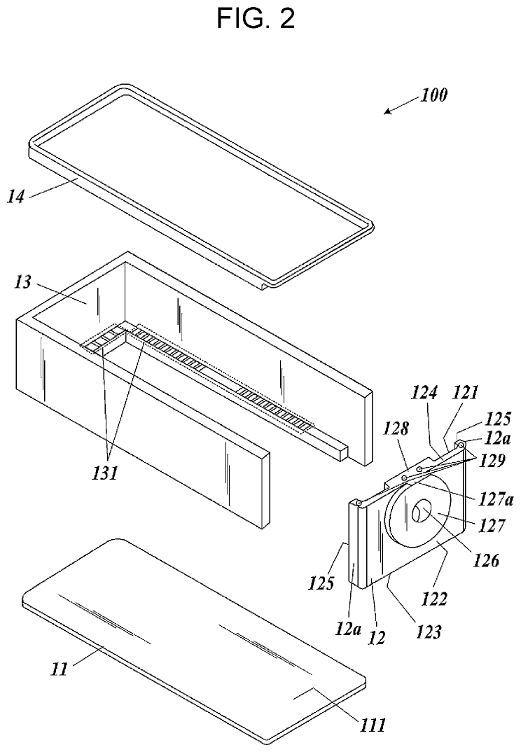

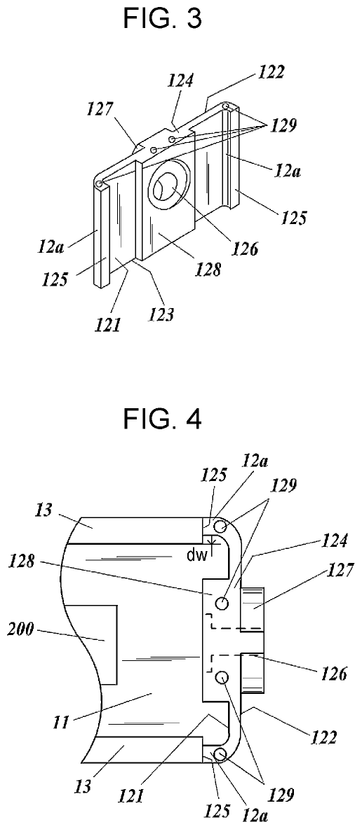

FIG. 2 is an exploded perspective view illustrating each configuration of the semiconductor package 100. In the exploded perspective view, the leads 15 are not shown. FIG. 3 is a view of the plate 12 viewed from the side of the inner surface 121.

The plate 12 includes a protrusion 128 (first protrusion) that is located on the inner surface 121 facing the space 10 and that is not in contact with the wall 13. The protrusion 128 is, for example, rectangular in shape, existing from an end on the upper end face 124 side to an end on the substrate 11 side in the up-down direction, and includes the through-hole 126. One end of the through-hole 126 is located substantially at the center of the protrusion 128.

Both end portions of the plate 12 are bent portions 12a bending toward the side of the inner surface 121 and extending toward the wall 13. In other words, the plate 12 has a U-shape. Thus, the two side end faces 125, which are joined to the wall 13, are parallel to the inner surface 121. Thus, the two side end faces 125 face the joint surfaces of the wall 13. The portions between the protrusion 128 and the bent portions 12a at both ends are relatively recessed. When the wall 13 and the frame 14 are joined to the plate 12, the joining material may protrude into the recessed portions from the joint surfaces.

A plurality of circular recesses 129 are located on the upper surface of the plate 12. The number of the recesses 129 is not particularly limited. For example, the same number of the recesses 129 are located on both sides of the through-hole 126; here, four recesses 129, two on the protrusion 128 and two on the bent portions at both ends, are located symmetrical to the center of the through-hole 126 in plan view. The plurality of recesses 129 may have the same shape. Each recess 129 may have a depth smaller than the height of the plate 12. When joining the frame 14 to the plate 12, the joining material flows into the recesses 129, thereby suppressing the joining material from flowing down along the inner surface 121 and the outer surface 122 of the plate 12, particularly into the through-hole 126, and fixing the frame 14 in a flat and stable manner.

The pipe-shaped protrusion 127 is located biased upward from the center on the outer surface 122 of the plate 12, with its outer edge reaching the upper end face 124. Accordingly, an outer edge upper portion 127a of the protrusion 127 is a continuous flat portion extending to the upper end face 124. Thus, the plate 12 can more stably support and fix the frame 14.

The lower surface of the frame 14 in contact with the plate 12 and the wall 13 is shaped to correspond to the heights of the plate 12 and the wall 13 from the upper surface 111. Here, since the plate 12 is higher than the wall 13, the thickness of the frame 14 (the width in a direction perpendicular to the plane including the frame 14) in the portion facing the plate 12 is smaller (thinner) than the thickness of the frame 14 in the portion facing the wall 13. As described above, since the frame 14 and the plate 12 are formed of the same material, particularly a material containing a metal such as a FeNiCo alloy, the risk of cracks or the like occurring during joining is reduced compared with a case where the components are formed of a ceramic material, even if the joint portion of the frame 14 to the plate 12 is thin. Thus, the height of the semiconductor package 100 can be reduced.

FIG. 4 is an enlarged plan view of a portion of the semiconductor package 100 near the plate 12 as viewed from above.

As described above, due to the protrusions 127 and 128, the plate 12 is partially thickened in a direction perpendicular to the plate 12 near the center, and the through-hole 126 is located in the thickened portion.

The two side end faces 125 parallel to the inner surface 121 are joined to the end faces of the wall 13. Here, the end faces of the wall 13 being joined are wider on the side of the space 10 by a width dw than the two side end faces 125. Thus, in the joining of the two side end faces 125 and the wall 13, brazing fillets can be formed between the bent portions at both ends of the plate 12 and the protrusion 128; therefore, the wall 13 and the plate 12 can have improved joining strength. In particular, since a large amount of protruding brazing material tends to be coated on the side of the plate 12, which is formed of a conductor metal, the wall 13 and the plate 12 can have improved joining strength more stably.

Note that the depression forming the brazing fillet may be disposed on the side of the wall 13 from the joined place. In other words, the wall 13 may be tapered so that the end faces thereof become partially narrower than the two side end faces 125 by a width dw.

Although not particularly limited, the plate 12 may be molded and produced using, for example, a formwork or the like that defines a three-dimensional shape. Alternatively, the plate 12 may be produced by punching, cutting, or the like. The recesses 129 may be included in the formwork or may be pressure-formed after the production in which a formwork that does not include the recesses is used. The recesses 129 may be added by application of pressure or the like when removing the plate 12 from the formwork. For example, as in MIM (Metal Injection Molding), pellets, which contain powder of the above-described conductor metal and binder and which are obtained by pressure kneading, may be heated and pushed into a formwork to injection-mold the plate 12.

The substrate 11 and the frame 14 may be produced in the same manner as the plate 12, in other words, by using a formwork or the like, or by punching, cutting, or the like.

In the production of the insulating layer (the wiring board) of the wall 13 including the signal lines and the grounding surface, for example, a metal paste is first prepared by mixing the above-described conductor metal, binder, and organic solvent. Next, a plurality of insulating sheets (ceramic green sheets), each obtained by forming a slurry obtained by mixing powder of a material substance (for example, aluminum oxide, silicon oxide, or the like) with an organic binder and a solvent into a sheet, are laminated. Here, the metal paste is applied by screen printing or the like to an insulating sheet that is either above or below the layer with the grounding surface or signal lines. Then, the laminated insulating sheets (including the applied metal paste) are crimped and fired (for example, heated at about 1600° C. in a reducing atmosphere). When portions other than the wiring board are insulating members, the process of applying the metal paste in the above-described production method is not necessary.

To obtain the semiconductor package 100 from the above-described substrate 11, plate 12, wall 13, frame 14, and the leads 15, first the leads 15 are brazed to the wall 13. Then, the substrate 11, the plate 12, and the wall 13 are brazed to each other, and thereafter the frame 14 is brazed to the plate 12 and the wall 13.

As described above, the semiconductor package 100 of the present embodiment includes the substrate 11 having the upper surface 111, the plate 12 including the through-hole 126, the wall 13 forming, together with the plate 12, the frame-shaped housing, and the frame 14. The frame-shaped housing is located on the substrate 11, and the frame 14 is located on the frame-shaped housing. The space 10 above the substrate 11 and enclosed by the frame-shaped housing is the mounting area of the electronic component 200. The plate 12 includes the through-hole 126 passing through in a planar direction of the upper surface 111 and includes the recesses 129 on the upper end face 124 facing the frame 14.

Thus, by including the recesses 129 on the joint surface of the upper end face 124 of the plate 12 with the frame 14, the joining material, such as the brazing material or the like, which joins the plate 12 and the frame 14, accumulates in the recesses 129. Thus, in the semiconductor package 100, inconvenience and defects due to the joining material protruding from the joint surface when crimping the members to be joined are reduced. Thus, in the semiconductor package 100, the members can be joined to each other more appropriately.

In the plate 12, the same number of recesses 129 having the same shape are located on the upper end face 124 across the through-hole 126 in perspective plan view. By including the same number of recesses 129 on the left and right sides of the upper end face 124, the amount of the accumulated brazing material tends to be uniform, such that the frame 14 can be joined to the plate 12 in a well-balanced manner.

The plate 12 is U-shaped in plan view of the upper surface 111, with both end portions extending toward the wall 13. The inner surface of the frame-shaped housing is depressed at the portion where the plate 12 faces the wall 13. Thus, the brazing material protruding from the joint surface stays in the depression, and thereby the inconvenience and defects that occur in the semiconductor package 100 can be reduced.

The wall 13 protrudes toward the space 10 at the portion (the joint surface) where the two side end faces 125 face the wall 13. Thus, the above-described depressed portion is further surrounded by the protruding portion of the wall 13; therefore, the spread of the joining material protruding from the joint surface between the plate 12 and the wall 13 to the upper surface 111 can be suppressed. The wider surface including the joint surface of the wall 13 enables the brazing fillet to be formed, which makes joining more stable and easier, such that the plate 12 and the wall 13 can have improved joining strength.

The plate 12 includes, at least on the upper end face 124, the protrusion 128 on the side facing the space 10, the protrusion 128 not being in contact with the wall 13. In other words, since the semiconductor package 100 includes a depression between the wall 13 and the through-hole 126, the joining material that protrudes from the joint surface when the plate 12 and the wall 13 are joined is easily guided into the depressed portion. Thus, the width of the flow of the joining material down to the upper surface 111 is reduced, and thereby the occurrence of the inconvenience and defects is reduced. In addition, since the central portion of the plate 12 is thicker in plan view, the plate 12 can have improved joining strength with the frame 14.

The plate 12 includes the outer surface 122 opposite to the inner surface 121 and the protrusion 127, which is located on the outer surface 122 and includes the through-hole 126. The edge of the through-hole 126 is the contact surface of a fixing terminal of a cable and the like inserted into the through-hole 126, and the outer edge of the protrusion 127 may be a surface to which the above-described fixing terminal is adhered by an adhesive material. Therefore, the semiconductor package 100 can stably support and fix the cable and the like.

The protrusion 127 includes the outer edge upper portion 127a that is a flat portion included in the upper end face 124. Since the pipe-shaped protrusion 127 does not have a fully annular outer shape, the height of the semiconductor package 100 can be reduced. Since the through-hole 126 is often not located in the center of the height direction of the plate 12 (specifically, the through-hole 126 is at a position upward from the center) due to the necessity of maintaining the balance with the internal electronic component 200, and the like, the upper end side of the protrusion 127 can be cut to be flush with the upper end face 124 to thereby make the joining with the frame 14 more stable and secure.

The thickness of the frame 14 in a portion in contact with the plate 12, in a direction perpendicular to the plane containing the frame 14, is thinner than the thickness of the frame 14 in the other portions not in contact with the plate 12. That is, the amount by which the plate 12 is higher than the wall 13 is adjusted by the difference in thickness of the frame 14. Thus, the height of the semiconductor package 100 can be reduced. In particular, when the plate 12 is formed of a FeNiCo alloy or the like, the frame 14 can be made thinner because cracks are less likely to occur under pressure and/or the like during joining. Since the plate 12 includes the protruding portions 127 and 128 and can thereby more stably support the frame 14, the frame 14 may be formed more thinly.

The semiconductor electronic device 1 of the present embodiment includes the above-described semiconductor package 100 and the electronic component 200 located in the above-described space 10. According to the semiconductor electronic device 1, the electronic component 200 is more securely housed in the semiconductor package 100 that is obtained by joining the members more stably. Thus, the generation of defective products can be reduced. The above embodiment is an example, and variations can be made.

For example, in the above embodiment, the plate 12 includes the protrusion 128 on the side of the inner surface 121 but is not limited to including the protrusion 128. When the plate 12 includes the protrusion 128, the protrusion 128 may be in contact with at least one side of the wall 13. The upper side of the protrusion 128 is not limited to being in the same plane as the upper end face 124, and the lower side is not limited to being in contact with the substrate 11.

The above embodiment is described based on an example in which the face of the wall 13 including the joint surface with the two side end faces 125 of the plate 12 is wider than the two side end faces 125 and protrudes to the side within a predetermined range, but is not limited to such an example. The surface where the wall 13 is joined to the two side end faces 125 may have the same width (length perpendicular to the height direction) as the two side end faces 125.

The above embodiment is described based on an example in which the plate 12 has a U-shape with the two end portions of the plate 12 bent to the side of the inner surface 121, but is not limited to such an example. The two side end faces 125 perpendicular to the inner surface 121 may be joined to the inner side end of the wall 13, or the side surfaces of the wall 13 may be joined to the two end portions of the inner surface 121 of the plate 12.

The joint surfaces of the plate 12 and the wall 13 are not limited to being simply planar. For example, the joint surfaces may include recessed and protruded portions mating with each other.

The above embodiment is described based on an example in which the protrusion 127 includes, on the side of the upper end face 124, the outer edge upper portion 127a in the same plane as the upper end face 124; however, when the annular protrusion 127 is entirely included within the outer surface 122 when viewed in front view in a direction perpendicular to the outer surface 122, the outer edge upper portion 127a is not provided in the annular protrusion 127.

The above embodiment is described based on an example in which the thickness of the frame 14 is non-uniform to match the difference in height between the plate 12 and the wall 13, but is not limited to such an example. When the height of the wall 13 is matched to the height of the plate 12, the thickness of the frame 14 may be uniform.

Specific details such as the configuration, structure, and manufacturing method described for the above-described embodiment can be appropriately changed without departing from the spirit of the present disclosure. The scope of the present invention includes the scope of the claims and the scope of the equivalents thereof.

### INDUSTRIAL AVAILABILITY

The present invention can be used in a semiconductor package and a semiconductor electronic device.

1. A semiconductor package comprising:
a substrate having an upper surface;
a plate comprising a through-hole;
a wall forming, together with the plate, a frame-shaped housing; and
a frame,
wherein the frame-shaped housing is located on the substrate,
the frame is located on the frame-shaped housing,
a space above the substrate and enclosed by the frame-shaped housing is a mounting area of an electronic component, and
the plate comprises the through-hole passing through in a planar direction of the upper surface and comprises a recess on a surface facing the frame.

2. The semiconductor package according to claim 1, wherein
a same number of recesses having a same shape are located on the surface facing the frame across the through-hole in perspective plan view.

3. The semiconductor package according to claim 1, wherein
the plate is U-shaped in plan view of the upper surface, with both ends extending toward the wall, and
an inner surface of the frame-shaped housing is depressed at a portion where the plate faces the wall.

4. The semiconductor package according to claim 3, wherein the wall protrudes toward the space at the portion where the plate faces the wall.

5. The semiconductor package according to any claim 1, wherein
the plate comprises, at least on the surface facing the frame, a first protrusion on a side facing the space, the first protrusion not being in contact with the wall.

6. The semiconductor package of claim 5, wherein
the plate comprises, on a surface opposite to a surface on which the first protrusion is located, a second protrusion comprising a through-hole.

7. The semiconductor package according to claim 6, wherein
the second protrusion comprises a flat portion extending to the surface facing the frame.

8. The semiconductor package according to claim 1, wherein
a thickness of the frame in a portion facing the plate is thinner than a thickness of the frame in a portion facing the wall.

9. A semiconductor electronic device comprising:
a semiconductor package according to claim 1, and
an electronic component located in the space.
